(19) United States
(12) Patent Application Publication
(10) Pub. No.: US 2021/0166939 A1
(43) Pub. Date: Jun. 3, 2021

(54) SUBSTRATE TREATING APPARATUS AND SUBSTRATE TREATING METHOD

(71) Applicant: SEMES CO., LTD., Chungcheongnam-do (KR)

(72) Inventors: Hae-Won CHOI, Daejeon (KR); Anton KORIAKIN, Chungcheongnam-do (KR)

(73) Assignee: SEMES CO., LTD

(21) Appl. No.: 17/100,382

(22) Filed: Nov. 20, 2020

(30) Foreign Application Priority Data
Nov. 28, 2019 (KR) 10-2019-0155153

(51) Int. Cl. H01L 21/027; H01L 21/67

(52) U.S. Cl. CPC H01L 21/0274; H01L 21/6715

(57) ABSTRACT

Embodiments of the inventive concept provide a substrate treating apparatus. According to an exemplary embodiment, the substrate treating apparatus comprises a first process chamber applying a process fluid containing an organic solvent to a substrate wet with a developer and introduced; and a second process chamber treating the substrate applied with the process fluid and introduced, through a supercritical fluid.

### CROSS-REFERENCE TO RELATED APPLICATIONS

A claim for priority under 35 U.S.C. § 119 is made to Korean Patent Application No. 10-2019-0155153 filed on Nov. 28, 2019, in the Korean Intellectual Property Office, the entire contents of which are hereby incorporated by reference.

### BACKGROUND

Embodiments of the inventive concept described herein relates to a substrate treating apparatus and a substrate treating method.

To fabricate a semiconductor device and a liquid crystal display panel, various processes, such as photolithography, etching, ashing, ion implanting, thin film deposition, and cleaning processes are performed. Among them, the photolithography process, which is to form a desired circuit pattern on a substrate, comprises coating, exposure, and developing processes which are sequentially performed. A photosensitive liquid, such as photoresist, is coated on the substrate in the coating process, the coated photoresist is exposed to an exposure light source in the exposing process, and either the exposed or non-exposed photoresist is selectively developed in the developing process. Thereafter, the developing liquid used in the developing process is removed from the substrate and then the substrate is dried.

### SUMMARY

Embodiments of the inventive concept provide a substrate treating apparatus and a substrate treating method, capable of effectively processing a substrate.

Embodiments of the inventive concept provide a substrate treating apparatus and a substrate treating method, capable of preventing a pattern from being damaged in the process of treating a substrate wet with a developer.

Embodiments of the inventive concept provide a substrate treating apparatus and a substrate treating method, capable of maintaining a uniform liquid film due to a stable wetting property, and capable of uniformly drying an entire substrate due to high properties of removing a developer and substituting by supercritical fluid.

The objects which will be achieved in the inventive concept are not limited to the above, but other objects, which are not mentioned, will be apparently understood to those skilled in the art.

Embodiments of the inventive concept provide a substrate treating apparatus.

According to an exemplary embodiment, the substrate treating apparatus comprises a first process chamber applying a process fluid containing an organic solvent to a substrate wet with a developer, and a second process chamber treating the substrate applied with the process fluid using a supercritical fluid.

According to an exemplary embodiment, the organic solvent may comprise any one of Decane, Dodecane, Di-butyl Ether, and O-xylene.

According to an exemplary embodiment, the first process chamber applies a first process fluid, which is pure water, to the substrate before applying the process fluid.

According to an exemplary embodiment, the process fluid may comprise a second process fluid applied to the substrate; and a third process fluid applied to the substrate after applying the second process fluid.

According to an exemplary embodiment, the second process fluid and the third process fluid may comprise Decane, Dodecane, Di-butyl Ether, and O-xylene.

According to an exemplary embodiment, the second process fluid may further comprise a surfactant.

According to an exemplary embodiment, the surfactant may be a nonionic surfactant.

According to an exemplary embodiment, the surfactant may be any one of Sorbitan trioleate, Sorbitan monooleate, Sorbitan monolaurate, Polyethylene glycol trimethylnonyl ether.

According to an exemplary embodiment, the developer may be a positive-type photoresist liquid.

Further, the inventive concept provides a substrate treating method for treating a substrate. According to an exemplary embodiment, the substrate treating method comprises applying a process fluid comprising an organic solvent to a substrate wet with the developer and treating the substrate applied with the process fluid using a supercritical fluid.

According to an exemplary embodiment, the organic solvent may comprise any one of Decane, Dodecane, Di-butyl Ether, and O-xylene.

According to an exemplary embodiment, the method may further comprise applying pure water to the substrate before applying the organic solvent.

According to an exemplary embodiment, the applying the process fluid may comprise supplying a mixture of a hydrophobic organic solvent and a surfactant to the substrate wet with the developer; and supplying the hydrophobic organic solvent to the substrate.

According to an exemplary embodiment, the hydrophobic organic solvent may comprise any one of Decane, Dodecane, Di-butyl Ether, and O-xylene.

According to an exemplary embodiment, the surfactant may be any one of Sorbitan trioleate, Sorbitan monooleate, Sorbitan monolaurate, Polyethylene glycol trimethylnonyl ether.

According to an exemplary embodiment, the developer may be a positive-type photoresist liquid.

Embodiments of the inventive concept treat a substrate efficiency.

In addition, embodiments of the inventive concept provide a substrate treating apparatus and a substrate treating method, capable of preventing a pattern from being damaged in the process of treating a substrate coated with a developer.

In addition, embodiments of the inventive concept provide a substrate treating apparatus and a substrate treating method, capable of maintaining a uniform liquid film due to a stable wetting property, and capable of uniformly drying an entire substrate due to high properties of removing a developer and substituting by supercritical fluid.

The inventive concept and methods of accomplishing the same may be understood more readily by reference to the following detailed description of embodiments and the accompanying drawings. However, the inventive concept may be embodied in many different forms, and should not be construed as being limited to the embodiments set forth herein. Rather, these embodiments are provided so that this inventive concept will be thorough and complete and will fully convey the concept of the invention to those skilled in the art, and the inventive concept will only be defined by the appended claims.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a plan view showing a substrate treating apparatus, according to an embodiment of the inventive concept.

FIG. 2 is a cross-sectional view showing a first process chamber of FIG. 1.

FIG. 3 is a cross-sectional view showing an example of a second process chamber of FIG. 1.

FIG. 4 shows a procedure of treating a substrate, according to an embodiment.

FIG. 5 shows an applying state of an organic solvent showing an unstable wetting property.

FIG. 6 shows an applying state of an organic solvent showing a stable wetting property.

### DETAILED DESCRIPTION

Hereinafter, an embodiment of the inventive concept will be described in more detail with reference to the accompanying drawings. The embodiments of the inventive concept may be modified in various forms, and the scope of the inventive concept should not be construed to be limited by the embodiments of the inventive concept described in the following. The embodiments of the inventive concept are provided to describe the inventive concept for those skilled in the art more completely. Accordingly, the shapes and the like of the components in the drawings are exaggerated to emphasize clearer descriptions.

Hereinafter, a substrate treating apparatus will be described according to the inventive concept.

The substrate treating apparatus may perform a supercritical process to treat a substrate using a supercritical fluid serving as a process fluid.

In this case, the substrate is a comprehensive concept comprising all substrates used to fabricate an article having a circuit pattern formed on a semiconductor device, a flat panel display (FPD), and other thin films. Such a substrate ‘S’ comprises, for example, a silicon wafer, a glass substrate, and an organic substrate.

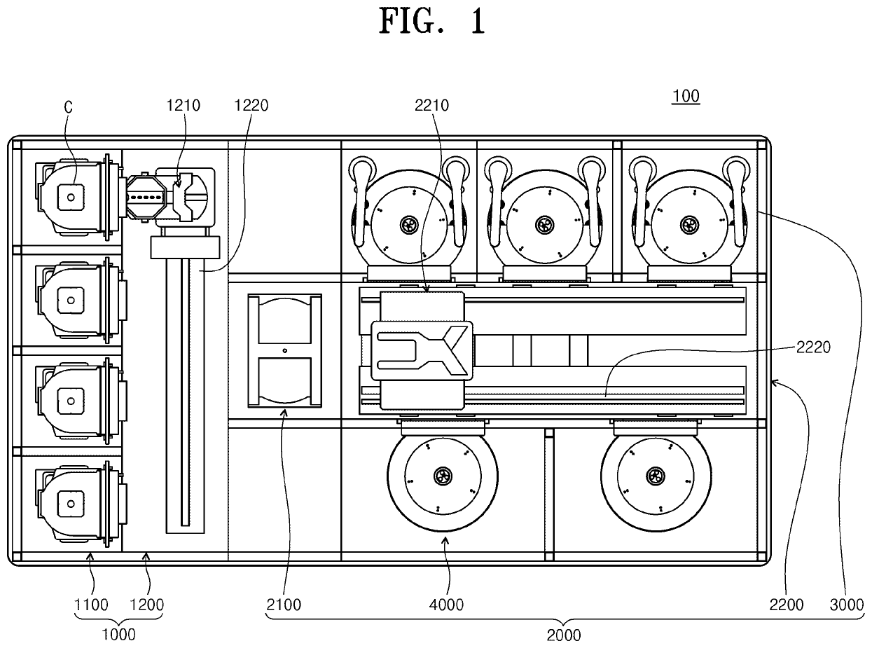

FIG. 1 is a plan view showing a substrate treating apparatus, according to an embodiment of the inventive concept.

Referring to FIG. 1, a substrate treating apparatus 100 may have an index module 1000 and a process module 2000.

The index module 1000 receives a substrate ‘S’ from an outside and carries the substrate ‘S’ to the process module 2000. The process module 2000 performs a substrate treating process using a supercritical fluid.

The index module 1000 comprises a load port 1100 and a transfer frame 1200, as equipment front end modules (EFEM).

A container ‘C’ is placed in the load port 1100 to receive the substrate ‘S’. A front opening unified pod (FOUP) may be used as the container ‘C’. The container ‘C’ may be introduced into the load port 1100 from the outside or withdrawn to the outside from the load port 1100 by Overhead Transfer (OHT).

The transfer frame 1200 carries the substrate ‘S’ between the container ‘C’ placed in the load port 1100 and the process module 2000. The transfer frame 1200 comprises an index robot 1210 and an index rail 1220. The index robot 1210 moves on the index rail 1220 and may carry the substrate ‘S’.

The process module 2000 comprises a buffer chamber 2100, a transfer chamber 2200, a first process chamber 3000, and a second chamber 4000.

The buffer chamber 2100 provides a space to temporarily stay the substrate ‘S’ carried between the index module 1000 and the process module 2000. A buffer slot may be provided in the buffer chamber 2100. The substrate ‘S’ is placed in the buffer slot. For example, the index robot 1210 may withdraw the substrate ‘S’ from the container ‘C’ and place the substrate ‘S’ in the buffer slot. The transfer robot 2210 of the transfer chamber 2200 may withdraw the substrate ‘S’ from the buffer slot and may carry the substrate ‘S’ to the first process chamber 3000 or the second process chamber 4000. A plurality of buffer slots may be provided in the buffer chamber 2100 to place a plurality of substrates ‘S’.

The transfer chamber 2200 carries the substrate ‘S’ among the buffer chamber 2100, the first process chambers 3000, and the second process chamber 4000 which are disposed around the transfer chamber 2200. The transfer chamber 2200 comprises a transfer robot 2210 and a transfer rail 2220. The transfer robot 2210 may move on the transfer rail 2220 to carry the substrate ‘S’.

The first process chamber 3000 and the second process chamber 4000 may perform a cleaning process using a process fluid. The cleaning process may be sequentially performed in the first process chamber 3000 and the second process chamber 4000. For example, the cleaning process may be performed in the first process chamber 3000 and a drying process using a supercritical fluid may be performed in the second process chamber 4000. In addition, a cleaning process and a drying process may be performed in the second process chamber 4000.

The first process chamber 3000 and the second process chamber 4000 are disposed on side of the transfer chamber 2200. For example, the first process chamber 3000 and the second process chamber 4000 may be arranged at opposite sides of the transfer chamber 2200.

A plurality of first process chambers 3000 and a plurality of second process chambers 4000 may be provided in the process module 2000. The plurality of process chambers 3000 and 4000 may be arranged in a line or be stacked at the side of the transfer chamber 2200, respectively. For example, the plurality of first process chambers may be arranged horizontally in a line or vertically stacked at the side of the transfer chamber 2200. Likewise, the plurality of second process chambers may be arranged horizontally in a line or vertically stacked at the side of the transfer chamber 2200.

The arrangement of the first process chamber 3000 and the second process chamber 4000 is not limited to the above-described example, and may be changed in consideration of a footprint or process efficiency of the substrate processing apparatus 100. The substrate processing apparatus 100 may be controlled by a controller.

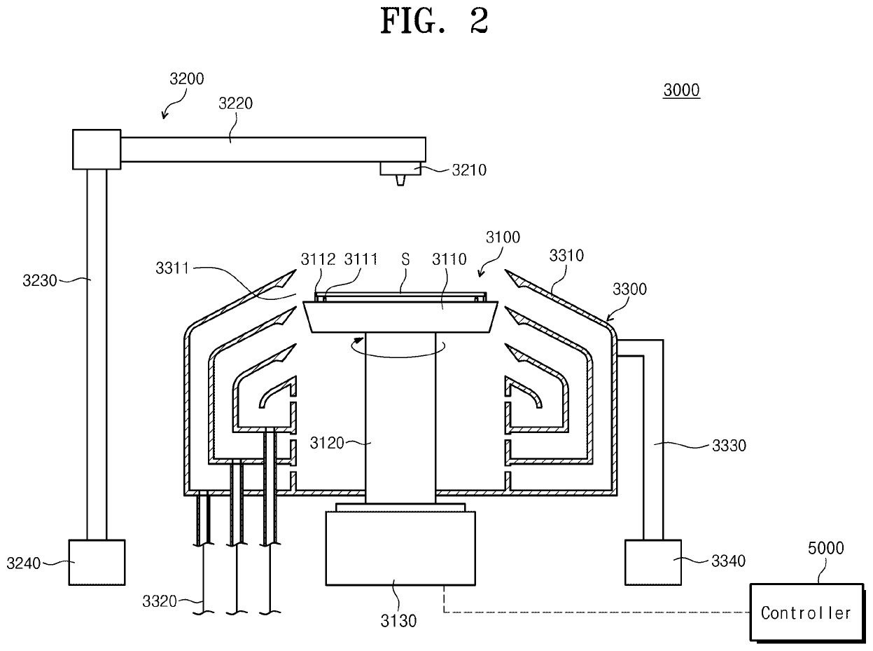

FIG. 2 is a cross-sectional view showing a first process chamber of FIG. 1.

Referring to FIG. 2, the first process chamber 3000 comprises a support unit 3100, a nozzle unit 3200, and a recovery unit 3300.

The first process chamber 3000 may clean the substrate using a substrate cleaning composition for cleaning the substrate. The process performed in the first process chamber 3000 is performed in the form of an anhydrous process that does not use water. Conventional chemical solutions, such as SC (Standard Clean)-1 and Dilute Hydrofluoric Acid (DHF), comprise water. A pattern formed on the substrate becomes gradually finer, and the line width of the pattern gradually becomes smaller. Since water has a surface tension, water is less infiltrated into a narrow space between patterns, resulting in a lower cleaning efficiency for the space between patterns. In addition, the chemical solution like SC-1 and DHF is applied in the conventional cleaning process, and the applied chemical solution is replaced by deionized water, and then deionized water is dried. In even the drying process, the substrate may have pattern leaning or pattern collapse. To the contrary, according to the inventive concept, the substrate cleaning composition is provided not to contain water. Accordingly, the problem caused by water contained in the conventional chemical solution does not occur.

The support unit 3100 supports the substrate ‘S’. The support unit 3100 may rotate the supported substrate ‘S’. The support unit 3100 comprises a support plate 3110, a support pin 3111, a chuck pin 3112, a rotating axis 3120, and a rotating driver 3130.

The support plate 3110 has a top surface in the shape which is the same as or similar to that of the substrate ‘S’. The support pin 3111 and the chuck pin 3112 are formed on the top surface of the support plate 3110. The support pin 3111 supports a bottom surface of the substrate ‘S’. The chuck pin 3112 may fix the substrate ‘S’ supported.

The rotating shaft 3120 is connected to a lower portion of the support plate 3110. The rotating shaft 3120 receives the rotational force from the rotating driver 3130 to rotate the support plate 3110. Accordingly, the substrate ‘S’ mounted on the support plate 3110 may rotate. The chuck pin 3112 prevents the substrate ‘S’ from deviating from a normal position.

The nozzle unit 3200 sprays a substrate cleaning composition onto the substrate ‘S’. The nozzle unit 3200 comprises a nozzle 3210, a nozzle bar 3220, a nozzle axis 3230, and a nozzle axis driver 3240.

The nozzle 3210 sprays the substrate cleaning composition on the substrate ‘S’ mounted on the support plate 3110. The nozzle 3210 is formed on one bottom surface of the nozzle bar 3220. The nozzle bar 3220 is coupled to the nozzle shaft 3230. The nozzle shaft 3230 is provided to be lifted or rotated. The nozzle shaft driver 3240 may adjust the position of a nozzle 3210 by lifting or rotating the nozzle shaft 3230.

The recovery unit 3300 recovers the substrate cleaning composition supplied to the substrate ‘S’. When the substrate cleaning composition is supplied to the substrate ‘S’ by the nozzle unit 3200, the support unit 3100 may rotate the substrate ‘S’ to uniformly supply the substrate cleaning composition to the entire area of the substrate ‘S’. When the substrate ‘S’ rotates, the substrate cleaning composition is scattered from the substrate ‘S’. The scattered substrate cleaning composition may be recovered by the recovery unit 3300.

The recovery unit 3300 comprises a recovery bowl 3310, a recovery line 3320, a lifting bar 3330, and a lifting driver 3340.

The recovery bowl 3310 is provided in the shape of an annular ring surrounding the support plate 3110. A plurality of recovery bowls 3310 may be provided. The plurality of recovery bowls 3310 may be provided in the shape of rings which are sequentially away from the support plate 3110 when viewed from the top. As the recovery bowl 3310 is at a longer distance from the support plate 3110, the recovery bowl 3310 has a higher height. A recovery port 3311 is formed in the space between the recovery bowls 3310 such that the substrate cleaning composition scattered from the substrate ‘S’ is introduced into the recovery port 3311.

The recovery line 3320 is formed on a bottom surface of the recovery bowl 3310.

The lifting bar 3330 is connected to the recovery bowl 3310. The lifting bar 3330 receives power from the lifting driver 3340 to move the recovery bowl 3310 up and down. When a plurality of recovery bowls 3310 are provided, the lifting bar 3330 may be connected to the outermost recovery bowl 3310. The lifting driver 3310 lifts the recovery bowl 3310 through the lifting bar 3330 to adjust one of the plurality of the recovery port 3311, which is to introduce the scattered substrate cleaning composition.

According to an embodiment of the inventive concept, the substrate cleaning composition comprises an organic solvent, a binder, and an etching compound. The details thereof will be described below after a description of FIG. 7.

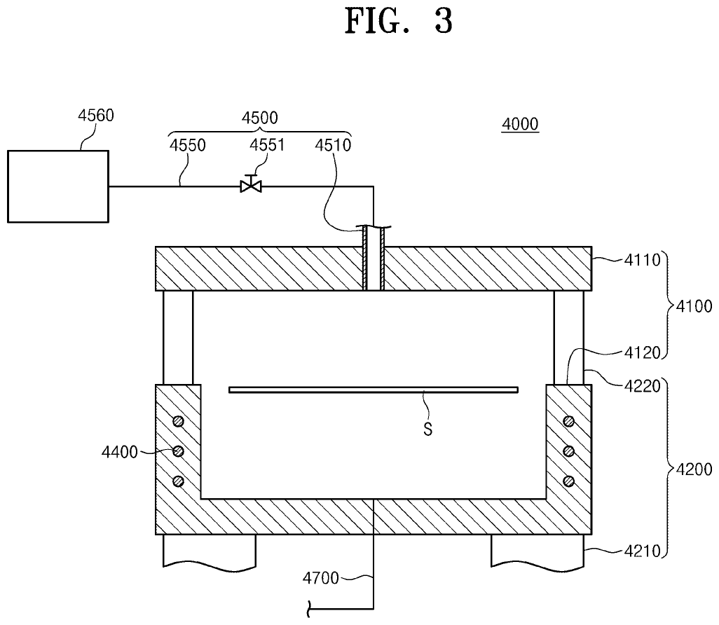

FIG. 3 is a cross-sectional view showing an example of a second process chamber of FIG. 1.

Referring to FIG. 3, the second process chamber 4000 comprises a chamber 4100, a lifting unit 4200, a support unit (not shown), a heating member 4400, a fluid supply unit 4500, a blocking member (not shown), and an exhaust member 4700. The second process chamber 4000 performs a substrate treating process using a supercritical fluid.

The chamber 4100 provides a treatment space in which a supercritical process is performed. The chamber 4100 is formed of a material to withstand high pressure which is equal to or greater than critical pressure.

The chamber 4100 comprises an upper body 4110 and a lower body 4120. The lower body 4120 is provided under the upper body 4110 while being coupled to the upper body 4110.

A space made through the combination of the upper body 4110 and the lower body 4120 is provided as a treatment space for performing the substrate treating process.

The upper body 4110 is fixedly mounted on the external structure. The lower body 4120 is provided to move up and down with respect to the upper body 4110. When the lower body 4120 moves down and spaces apart from the upper body 4110, the treatment space inside the second process chamber 4000 is open and the substrate ‘S’ may be introduced into or withdrawn from the treatment space.

When the lower body 4120 moves up and makes close contact with the upper body 4110, the treatment space inside the second process chamber 4000 is closed. In the closed treatment space, the substrate ‘S’ may be treated using the supercritical fluid. Unlike described above, the chamber 4100 may be provided such that the lower body 4120 is fixedly mounted and the upper body 4110 moves up and down.

The lifting unit 4200 lifts the lower body 4120. The lifting unit 4200 comprises a lifting cylinder 4210 and a lifting rod 4220. The lifting cylinder 4210 is coupled to the lower body 4120 to generate driving force in a vertical direction. During performing substrate treatment using the supercritical fluid, the lifting cylinder 4210 generates the driving force capable of overcoming high pressure equal to or greater than critical pressure inside the second process chamber 4000, and of bringing the lower body 4120 into contact the upper body 4110 to close the second process chamber 4000. The lifting rod 4220 has one end inserted in to the lifting cylinder 4210 to extend in the vertical direction such that an opposite end of the lifting rod 4220 is coupled to the upper body 4110. When the driving force is generated from the lifting cylinder 4210, the lifting cylinder 4210 and the lifting rod 4220 relatively move up and down such that the lower body 4120 coupled to the lifting cylinder 4210 moves up and down. While the lower body 4120 moves up and down by the lifting cylinder 4210, the lifting rod 4220 prevents the upper body 4110 and the lower body 4120 from moving in the horizontal direction, guides moving-up and moving-down directions, and prevents the upper body 4110 and the lower body 4120 from deviating from the normal positions.

The support unit (not shown) is positioned in the treatment space of the chamber 4100 to support the substrate ‘S’. The support unit (not shown) is coupled to the upper body 4110 or the lower body 4220.

The support unit (not shown) makes contact with an edge area of the substrate ‘S’ to support the substrate ‘S’. The supported substrate ‘S’ may be treated using the supercritical fluid with respect to an entire top surface thereof and a most part of the bottom surface thereof. In this case, the substrate ‘S’ may have a patterned top surface and a non-patterned bottom surface.

The heating member 4400 heats the inside of the second process chamber 4000. The heating member 4400 heats the supercritical fluid, which is supplied into the second process chamber 4000, to a critical temperature or higher such that the supercritical fluid is maintained to be in a supercritical fluid phase. If the supercritical fluid is liquified, the heating member 4400 may heat the liquified supercritical fluid to become a supercritical fluid again. The heating member 4400 is buried and installed in at least one of the upper body 4110 and the lower body 4120. The heating member 4400 receives power from the outside to generate heat. For example, the heating member 4400 may be provided in a heater.

The fluid supply unit 4500 supplies fluid to the second process chamber 4000. The supplied fluid may be the supercritical fluid. For example, the supplied supercritical fluid may be carbon dioxide. In addition, the fluid supply unit 4500 may supply a mixture of the supercritical fluid and the substrate cleaning composition.

The fluid supply unit 4500 comprises a fluid supply port 4510, a supply line 4550, and a valve 4551.

The fluid supply port 4510 is to directly supply the supercritical fluid to the top surface of the substrate ‘S’. The fluid supply port 4510 is provided to be connected to the upper body 4110. The fluid supply port 4510 may further comprise a lower fluid supply port (not shown) connected to the lower body 4120. The supercritical fluid sprayed from the fluid supply port 4510 reaches the central area of the substrate ‘S’ and spreads to the edge area of the substrate ‘S’ thereby uniformly provided to the entire area of the substrate ‘S’.

The supply line 4550 is connected to the fluid supply port 4510. The supply line 4550 receives the supercritical fluid from a separate supercritical fluid storage unit 4560, which is placed outside, to supply the supercritical fluid to the fluid supply port 4510. For example, the supercritical fluid storage unit 4560 stores a supercritical fluid, which may be carbon dioxide, and supplies the supercritical fluid to the supply line 4550.

The valve 4551 is mounted on the supply line 4550. A plurality of valves 4551 may be provided on the supply line 4550. The valves 4551 adjust an amount of the supercritical fluid supplied to the fluid supply port 4510. The valve 4551 may control an amount of a fluid supplied into the chamber 4100 by a controller 5000.

A blocking member (not shown) prevents the supercritical fluid, which is supplied from the fluid supply unit 4500, from directly being sprayed to the substrate 5′. The blocking member (not shown) is positioned in the treatment space inside the chamber 4100. The blocking member (not shown) is provided between the support unit (not shown) and the fluid supply port 4510. The blocking member (not shown) may be provided in the shape of a circular plate.

The exhaust member 4700 exhausts the supercritical fluid from the second process chamber 4000. The exhaust member 4700 may be connected to an exhaust line 4750 that exhausts the supercritical fluid. In this case, a valve (not shown) for adjusting an amount of the supercritical fluid exhausted to the exhaust line may be mounted on the exhaust member 4700. The supercritical fluid exhausted through the exhaust line may be discharged into the atmosphere or supplied to a supercritical fluid regeneration system (not shown). The exhaust member 4700 may be coupled to the lower body 4120.

At the later stage of the substrate treating process using the supercritical fluid, the supercritical fluid may be exhausted from the second process chamber 4000, and the inner pressure of the process chamber 4000 may be reduced below critical pressure such that the supercritical fluid is liquified. The liquified supercritical fluid may be discharged through the exhaust member 4700, which is formed in the lower body 4120, by gravity.

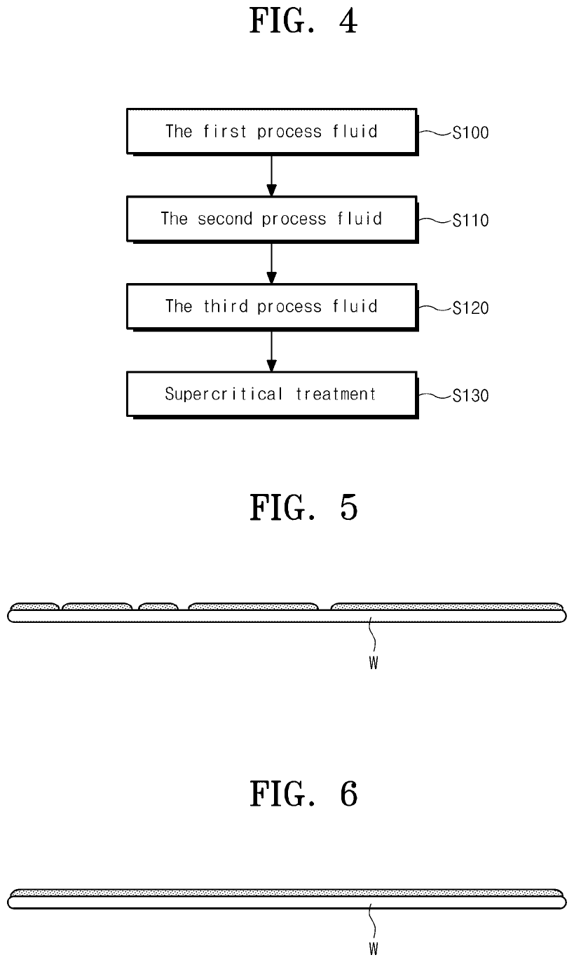

FIG. 4 shows a procedure of treating a substrate, according to an embodiment.

Referring to FIG. 4, the substrate processing apparatus 100 treats the substrate ‘S’ which is wet with a developer and introduced, according to a setting process. The substrate ‘S’ as wet with a developer matched with a positive photoresist after coated with a positive photoresist and exposed, is introduced into the processing apparatus. For example, the developer wet onto the substrate ‘S’ may be tetramethylammonium hydroxide (TMAH).

A first process fluid is supplied to the substrate ‘S’ (S100). The first process fluid may rinse the substrate ‘S’ wet with the developer. The first process fluid may be pure water.

Thereafter, a second process fluid is supplied to the substrate ‘S’ (S110). The second process fluid is provided in a mixture of a hydrophobic organic solvent and a surfactant. The hydrophobic organic solvent may be any one of Decane, Dodecane, Di-butyl Ether, and O-xylene. Decane, Dodecane, Di-butyl Ether, and O-xylene are a stable wetting property. If Heptane is applied as the organic solvent, Heptane has an unstable wetting property within seconds to tens of seconds after applying the fluid, and accordingly a pattern leaning phenomenon is occurred. Herein, referring to FIG. 5, the unstable wetting property means that a film is not uniformly formed on the substrate due to breaking of liquid films. However, if Decane, Dodecane, Di-butyl Ether, and O-xylene are applied as the organic solvent, the stable wetting may be possible referring to FIG. 6 without the above described problem.

The present inventors, without being bound by any theory, believe that the wetting property described above depends on the boiling point, density, viscosity, and evaporation rate of the organic solvent. For example, Heptane can easily break the liquid film due to low density, low viscosity (low gravitation which is movement towards or attraction among molecules), low surface tension, and high evaporation rate. Therefore, Heptane is not uniformly evaporated and dried. However, Decane, Dodecane, Di-butyl Ether, and O-xylene are relatively high boiling point, high density, high viscosity, and low evaporation rate so that the stable wetting can be possible, and they are uniformly evaporated and dried.

Referring to FIG. 4 again, as the second process fluid comprises the surfactant, the hydrophilic first process fluid, which is applied to the substrate ‘5’, is smoothly replaced by the second process fluid comprising the hydrophobic organic solvent. The surfactant having a Hydropilic-Lipophilic Balance in the range of 7 to 9 is used. According to an exemplary embodiment, the surfactant is a nonionic surfactant. According to an exemplary embodiment, the surfactant is Sorbitan Esters. According to an exemplary embodiment, Sorbitan Esters may be any one of Sorbitan trioleate (SPAN85), Sorbitan monooleate (SPAN80), Sorbitan monolaurate (SPAN20). In addition, the surfactant may be Polyethylene glycol trimethylnonyl ether. Polyethylene glycol trimethylnonyl ether may be any one of TMN-6 of TERGITOL-type or TMN-10 of TERGITOL-type. Preferably, the surfactant is Sorbitan trioleate (Span85).

According to the detection of the present inventors, the length of a tail 1, which is a lipophile of Span85, is longer than tail 1 of Span80 and tail 1 of Span20, or the number of tails 1 is larger than those of Span80 and Span20. Thus, even though water substitutionality of Span85 is lower than those of Span80 and Span20, Span85 has higher sub stitutionality with a third process fluid to be supplied thereafter, and even has higher sub stitutionality with the supercritical fluid. The present inventors founded out that 90% or more of Leaning Free is caused when a mixed liquor of Heptane and Span85 is used as the second process fluid. In addition, the present inventors founded out that TMN-6 and TMN-10 have Hydropilic-Lipophilic Balance similar to Span20.

Thereafter, the third process fluid is supplied to the substrate ‘S’ (S120). The third process fluid is provided in a hydrophobic organic solvent. The hydrophobic organic solvent may be any one of Decane, Dodecane, Di-butyl Ether, and O-xylene. A switching from supplying the second process fluid to supplying the third process fluid may be performed sequentially. For example, in the process of supplying the hydrophobic organic solvent containing the surfactant, a method of blocking the surfactant mixed with the hydrophobic organic solvent may be the switching from supplying the second process fluid to supplying the third process fluid may be performed. In this case, the surfactant is mixed with a set amount of hydrophobic organic solvent, and the mixture is supplied, and its supplied process may be stopped. In addition, an amount of the surfactant contained in the hydrophobic organic solvent may be reduced while the second process fluid is being supplied. In addition, the supplying of the second process fluid and the supplying of the third process fluid may be not continuously performed. That is, the supplying of the second process is performed, and stopped, and then the third process is performed.

The first process fluid to the third process fluid may be applied in the first process chamber 3000.

Thereafter, the substrate ‘S’ is introduced into the second process chamber 4000 in the state that the third process fluid remains on the substrate ‘S’. When the substrate ‘S’ is introduced, the second process chamber 4000 removes the third fluid from the substrate ‘S’ by supplying the supercritical fluid (S130).

According to the inventive concept, the substrate ‘S’ wet with the developer is treated using the supercritical fluid to prevent the pattern from being collapsed in the process of treating and drying the substrate ‘S’ after wetting the developer. In addition, a hydrophilic organic solvent, such as isopropyl alcohol (IPA), may cause damage to photoresist for forming the pattern in the process of reacting with the supercritical fluid. To the contrary, according to the inventive concept, when the substrate ‘S’ is exposed to the supercritical fluid, the substrate does not have the hydrophilic organic solvent and thereby preventing the pattern from being damaged.

According to another embodiment, after the first process fluid is supplied, the second process fluid supplied to the substrate ‘S’ may be the hydrophilic organic solvent. For example, the hydrophilic organic solvent may comprise IPA. As the second process fluid is provided as the hydrophilic organic solvent, the first process fluid applied on the substrate ‘S’ may be effectively replaced by the second process fluid.

Thereafter, similarly, after supplying the third process fluid, i.e., the hydrophilic organic solvent, the substrate is dried by the supercritical fluid. As the third process fluid is provided in an organic solvent similar to the second process fluid, the third process fluid may be effectively replaced by the second process fluid.

The above description has been made for the illustrative purpose. Furthermore, the above-mentioned contents describe the exemplary embodiment of the inventive concept, and the inventive concept may be used in various other combinations, changes, and environments. That is, the inventive concept can be modified and corrected without departing from the scope of the inventive concept that is disclosed in the specification, the equivalent scope to the written disclosures, and/or the technical or knowledge range of those skilled in the art. The written embodiment describes the best state for implementing the technical spirit of the inventive concept, and various changes required in the detailed application fields and purposes of the inventive concept can be made. Accordingly, the detailed description of the inventive concept is not intended to limit the inventive concept to the disclosed embodiments. Furthermore, it should be construed that the attached claims include other embodiments.

What is claimed is:

1. An apparatus for treating a substrate, the apparatus comprising:
a first process chamber applying a process fluid containing an organic solvent to a substrate wet with a developer; and
a second process chamber treating the substrate applied with the process fluid using a supercritical fluid.

2. The apparatus of claim 1, wherein the organic solvent comprises any one of Decane, Dodecane, Di-butyl Ether, and O-xylene.

3. The apparatus of claim 1, wherein the first process chamber applies a first process fluid, which is pure water, to the substrate before applying the process fluid.

4. The apparatus of claim 1, wherein the process fluid comprises:
a second process fluid applied to the substrate; and
a third process fluid applied to the substrate after applying the second process fluid.

5. The apparatus of claim 4, wherein the second process fluid and the third process fluid comprise any one of Decane, Dodecane, Di-butyl Ether, and O-xylene.

6. The apparatus of claim 4, wherein the second process fluid further comprises a surfactant.

7. The apparatus of claim 6, wherein the surfactant is a nonionic surfactant.

8. The apparatus of claim 6, wherein the surfactant is any one of sorbitan trioleate, sorbitan monooleate, sorbitan monolaurate, and polyethylene glycol trimethylnonyl ether.

9. The apparatus of claim 1, wherein the developer is a positive-type photoresist liquid.
